(19) United States
(12) Patent Application Publication
(10) Pub. No.: US 2010/0007932 A1
(43) Pub. Date: Jan. 14, 2010

(54) Optical recording medium and method for manufacturing the same

(75) Inventors: Motohiro Inoue, Tokyo (JP); Jiro Yoshinari, Tokyo (JP); Atsuko Kosuda, Tokyo (JP); Naoki Hayashida, Tokyo (JP); Hajime Utsunomiya, Tokyo (JP)

Correspondence Address: OLIFF & BERRIDGE, PLC, P.O. BOX 320850, ALEXANDRIA, VA, 22320-4850, US

(73) Assignee: TDK CORPORATION, Tokyo (JP)

(21) Appl. No.: 12/457,195

(22) Filed: Jun. 3, 2009

(30) Foreign Application Priority Data
Jul. 8, 2008 (JP) 2008-177666

(51) Int. Cl. G03H 1/02; G03F 7/00

(52) U.S. Cl. 359/3; 430/2

(57) ABSTRACT

An optical recording medium has a recording layer formed of a plurality of reflection hologram layers. A spacer layer is interposed between the respective reflection hologram layers. The reflection hologram layer is made of a material having a thermal threshold value which allows, when being irradiated with a recording laser beam, local absorbed heat to vary hologram diffraction conditions at a focal position, and allows the hologram to be retained at non-focal positions. The spacer layer is made of a material which is insensitive to a laser beam of a recording wavelength and which has a smaller extinction coefficient than that of the reflection hologram layer.

### BACKGROUND OF THE INVENTION

1. Field of the Invention

The present invention relates to an optical recording medium on which information is recorded as a micro-local transformation within a reflection hologram layer and to a method for manufacturing the same.

2. Description of the Related Art

Japanese Translation of PCT International Application No. 2002-502057 discloses a device which enables recording of information on each local transformation region formed in format hologram layers of a holography storage medium. The local transformation region is selectively formed by focusing a high-power laser beam on a desired storage position in the format hologram layers formed at multiple depths in a recording layer of the medium.

This information recording is performed in a manner such that the format hologram layer is irradiated with a high-power recording laser beam to destroy the diffraction conditions of a reflection hologram at a local portion thereof, thereby forming a local transformation region having a worse reflection property than its surrounding portions.

However, the device may destroy the diffraction conditions of the reflection hologram even at other than the focal position of the recording laser beam in the format hologram layer, thus causing inaccurate recording of information.

### SUMMARY OF THE INVENTION

In view of the foregoing problems, various exemplary embodiments of this-invention provide an optical recording medium which has a plurality of reflection hologram layers formed therein. The optical recording medium also has an absorption contrast that the recording laser beam used to irradiate the recording medium is more absorbed at its focal position than at any other portion, and further allows its diffraction conditions to vary due to decomposition by locally absorbed heat at the focal position. Various exemplary embodiments of the invention also provide a method for manufacturing such an optical recording medium.

In summary, the above-described objectives are achieved by the following aspects of the present invention.

(1) An optical recording medium comprising an information recording layer formed of a plurality of reflection hologram layers, the information recording layer being irradiated with a recording laser beam to record information as a local transformation within the reflection hologram layers, wherein the plurality of reflection hologram layers are stacked in layers with a spacer layer interposed therebetween, and the spacer layer is insensitive to a recording wavelength laser beam and has a smaller extinction coefficient than that of the reflection hologram layers.

(2) The optical recording medium according to (1), wherein the reflection hologram layer is made of a material having a thermal threshold value which allows, when being irradiated with a focused recording laser beam, at a focal position, local absorbed heat to vary diffraction conditions to form a local transformation, thereby recording information, and at a non-focal position, the diffraction conditions to be maintained.

(3) The optical recording medium according to (1) or (2), wherein a number, a thickness, and a material of the reflection hologram layers, and a number and an extinction coefficient of the spacer layers are selected such that all diffracted beams obtained when each reflection hologram layer is irradiated with a focused reproduction laser beam have a reflectivity greater than 0.01%, and an increase in temperature at a position of a reflection hologram layer irradiated with a focused recording laser beam is greater than 100° C.

(4) The optical recording medium according to any one of (1) to (3), wherein: the reflection hologram layer and the spacer layer are alternately deposited on one side of a support substrate having a servo pit or groove on the one side; and a protection layer is formed outside an outermost reflection hologram layer.

(5) The optical recording medium according to (4), wherein a reflective layer is formed on a surface of the servo pit or groove of the support substrate.

(6) The optical recording medium according to (4) or (5), wherein the reflection hologram layer is formed such that the one side has a cross-sectional shape along the servo pit or groove, and its opposite side is flat in shape.

(7) The optical recording medium according to any one of (4) to (6), wherein the support substrate is of a disc shape, and the servo pit or groove has a track pitch of any of 0.32 μm and 0.74 μm.

(8) A method for manufacturing an optical recording medium, the method comprising the-steps of: forming a photosensitive layer on one side of a support substrate; forming a reflection hologram layer by exposing the photosensitive layer to an interference pattern and fixing a reflection hologram having been formed by the exposure to the interference pattern; on the reflection hologram layer, forming a spacer layer being insensitive to a laser beam of a recording wavelength and having a smaller extinction coefficient than that of the reflection hologram layer; and alternately depositing a plurality of reflection hologram layers and spacer layers on the spacer layer by repeating the steps of sequentially forming a photosensitive layer, a reflection hologram layer, and a spacer layer in the same manner as above, wherein the reflection hologram layer is made of a material whose diffraction conditions vary, when being irradiated with a recording laser beam, as a local transformation at a focal position.

(9) A method for manufacturing an optical recording medium, the method comprising the steps of: forming a photosensitive layer on one side of a support substrate; forming a spacer layer on the photosensitive layer, the spacer layer being insensitive to a laser beam of a recording wavelength; forming a reflection hologram layer by exposing the photosensitive layer to an interference pattern via the spacer layer and fixing a reflection hologram having been formed by the exposure to the interference pattern; and alternately depositing a plurality of reflection hologram layers and spacer layers on the spacer layer by repeating the steps of sequentially forming a photosensitive layer and a spacer layer and forming a reflection hologram layer by the exposure to an interference pattern in the same manner as above, wherein the reflection hologram layer is made of a material whose diffraction conditions vary, when being irradiated with a recording laser beam, as a local transformation at a focal position, and the spacer layer is formed to have a smaller extinction coefficient than that of the reflection hologram layer.

(10) A method for manufacturing an optical recording medium, the method comprising the steps of: forming a photosensitive layer on one side of a support substrate; forming a spacer layer on the photosensitive layer, the spacer layer being insensitive to a laser beam of a recording wavelength; alternately depositing a plurality of photosensitive layers and spacer layers on the spacer layer by repeating steps of sequentially forming a photosensitive layer and a spacer layer in the same manner as above; and forming a reflection hologram layer by collectively exposing the plurality of stacked photosensitive layers to an interference pattern and fixing a reflection hologram having been formed by the exposure to the interference pattern, wherein the reflection hologram layer is made of a material whose diffraction conditions vary, when being irradiated with a recording laser beam, as a local transformation at a focal position, and the spacer layer is formed to have a smaller extinction coefficient than that of the reflection hologram layer.

(11) The method for manufacturing an optical recording medium according to any one of (8) to (10), wherein the support substrate has a servo pit or groove, and the method comprising the steps of: pre-forming a reflective layer of a dielectric material on the servo pit or groove of the support substrate; on the photosensitive layer that is formed on the reflective layer, depositing repeatedly a spacer layer, a reflective layer, and a photosensitive layer in that order; and before forming the reflective layer on each of the spacer layers, forming on the spacer layer a servo groove similar to the servo groove.

(12) A method for manufacturing an optical recording medium, comprising the step of: affixing one side of a land/groove substrate having a reflective layer formed on a land/groove side via an adhesive layer to one side of a support substrate of a layered structure, the layered structure having a plurality of reflection hologram layers and spacer layers alternately deposited on the other side of the support substrate, wherein the reflection hologram layer is made of a material whose diffraction conditions vary, when being irradiated with a recording laser beam, as a local transformation at a focal position, and the spacer layer is formed to have a smaller extinction coefficient than that of the reflection hologram layer.

### BRIEF DESCRIPTION OF THE DRAWINGS

FIG. 1 is a perspective view illustrating an optical recording medium according to an exemplary embodiment of the present invention;

FIG. 2 is a magnified schematic view illustrating the cross section taken along line II-II of FIG. 1;

FIG. 3 shows schematic cross-sectional views illustrating the steps of manufacturing an optical recording medium by a manufacturing method according to a first exemplary embodiment of the present invention;

FIG. 4 shows a flowchart of the manufacturing method of the first exemplary embodiment;

FIG. 5 is a schematic cross-sectional view illustrating the optical recording medium of the first exemplary embodiment when laser beams of different wavelengths are used for recording/reproduction and servo operations;

FIG. 6 shows schematic cross-sectional views illustrating the steps of manufacturing an optical recording medium by a manufacturing method according to a second exemplary embodiment of the present invention;

FIG. 7 shows a flowchart of the manufacturing method of the second exemplary embodiment;

FIG. 8 is a schematic cross-sectional view illustrating the steps of manufacturing an optical recording medium by a manufacturing method according to a third exemplary embodiment of the present invention;

FIG. 9 shows a flowchart of the manufacturing method of the third exemplary embodiment;

FIG. 10 shows schematic cross-sectional views illustrating the steps of manufacturing an optical recording medium by a manufacturing method according to a fourth exemplary embodiment of the present invention;

FIG. 11 shows a flowchart of the manufacturing method of the fourth exemplary embodiment;

FIG. 12 shows schematic cross-sectional views illustrating the main steps of manufacturing an optical recording medium by a manufacturing method according to a fifth exemplary embodiment of the present invention;

FIG. 13 shows schematic cross-sectional views illustrating the steps of manufacturing an optical recording medium by a manufacturing method according to a sixth exemplary embodiment of the present invention;

FIG. 14 shows a flowchart of the manufacturing method of the sixth exemplary embodiment;

FIG. 15 is a diagram showing increases in reflectivity and temperature for each reflection hologram layer of an optical recording medium according to an example of the present invention;

FIG. 16 is a diagram showing the relationship between the increase in temperature and time;

FIG. 17 is a diagram showing the relationship between the increase in temperature and the duration of irradiation with a laser beam in the reflection hologram layer at the focal position and in an adjacent reflection hologram layer according to the aforementioned example;

FIG. 18 is a diagram showing the relationship between the increase in temperature of and the depth from the point of incidence of the laser beam on the reflection hologram layer at the focal position and its adjacent spacer layers according to the aforementioned example;

FIG. 19 is a diagram showing the relationship between the distance from the beam spot on the first reflection hologram layer from the side of light incidence and the increase in temperature according to the aforementioned example; and

FIG. 20 is a diagram showing the relationship between the distance from the beam spot on the twentieth reflection hologram layer from the side of light incidence and the increase in temperature according to the aforementioned example.

### PREFERRED EMBODIMENTS OF THE INVENTION

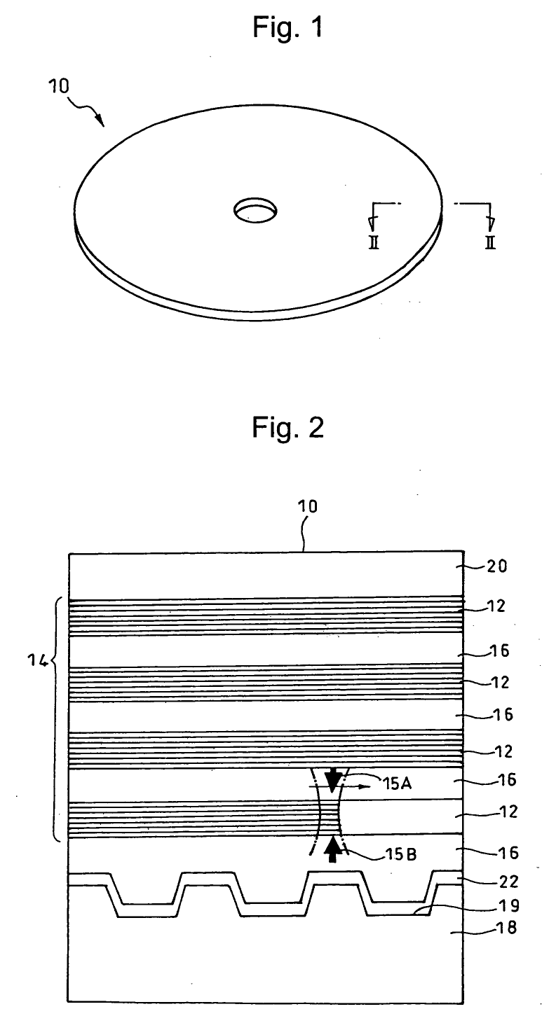

As shown in FIG. 1, an optical recording medium 10 according to an example of the present invention is formed in the shape of a disc, which as shown in FIG. 2, has a recording layer 14 with a plurality of reflection hologram layers 12 formed in the direction of thickness.

The plurality of reflection hologram layers 12 are separated from each other by a spacer layer 16 interposed therebetween.

Furthermore, as shown in FIG. 2, these alternately deposited reflection hologram layers 12 and spacer layers 16 are formed on a support substrate 18, and a protection layer 20 is further formed outside the outermost (in the figure, the uppermost) reflection hologram layer 12.

Like the support substrate for the Blu-ray (trademark) disc, the support substrate 18 has grooves 19 at track pitch intervals of 0.32 μm, and is provided on the groove 19 side surface with a reflective layer 22 that has been deposited by sputtering a dielectric material such as SiO₂.

The reflection hologram layer 12 is made of a photosensitive material having a thermal threshold value at which its hologram diffraction conditions vary at a focal position due to heat absorbed when being irradiated with a recording laser beam but the hologram is maintained at a non-focal position. For example, the layer 12 is made of a photopolymer which has incorporated a monomer having absorption at the wavelength of the recording laser beam. Here, the monomer has a modified component element that is thermally decomposed due to heat absorbed when being irradiated with the recording laser beam, or has incorporated a dye that is likely to be thermally decomposed.

The spacer layer 16 is made of a material which is insensitive to the laser beam of a recording wavelength and has a smaller extinction coefficient than that of the reflection hologram layer 12. For example, the material may be a photocurable resin, a thermosetting resin, or a thermoplastic resin such as polycarbonate.

For example, the support substrate 18 may be made of a glass substrate, and the protection layer 20 may be made of a sheet of transparent photocurable resin or polycarbonate. Note that the protection layer 20 can be made of the material for the spacer layer 16. Suppose that a spacer layer is provided outside the outermost reflection hologram layer 12 and then the same material as that of the spacer layer is used to cover the outside thereof. In this case, the spacer layer and the material layer of the protection layer are added up to form the final protection layer.

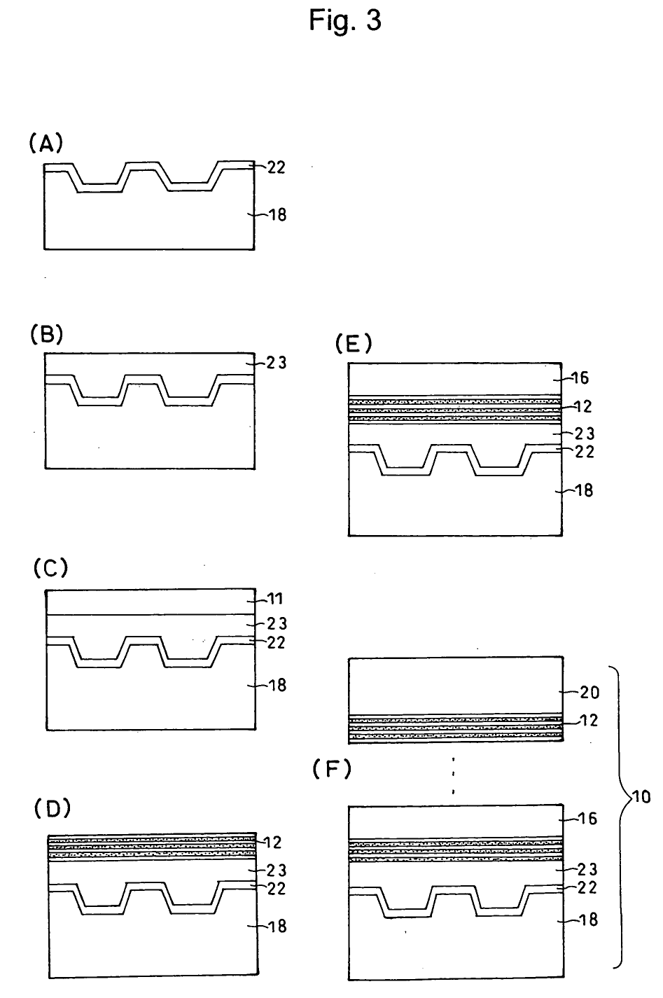

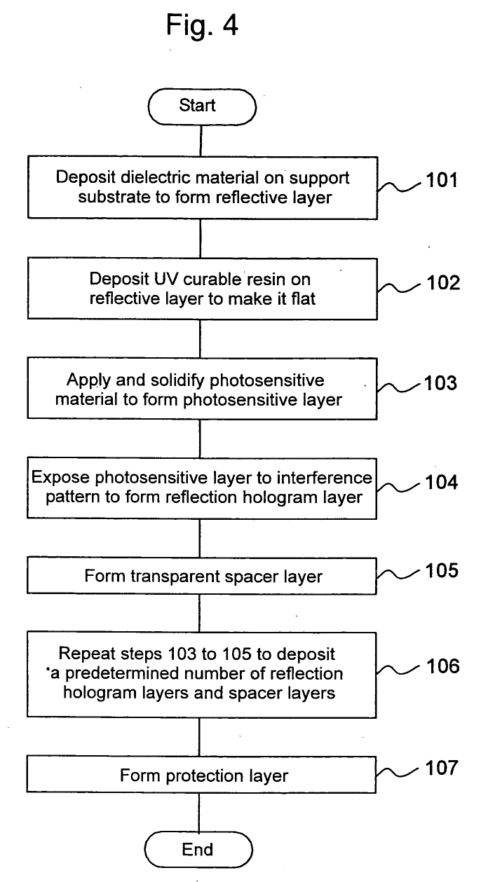

With reference to FIGS. 3 and 4, a description will now be given of the steps for manufacturing the aforementioned optical recording medium 10.

First, in step 101 (see FIG. 4), the reflective layer 22 is formed on the support substrate 18 having the grooves 19 through deposition of a dielectric material by sputtering or the like (see FIG. 3A).

Next, in step 102, a transparent photocurable resin 23 or the like is deposited on the reflective layer 22, for example, by spin coating, slot coating, or screen printing, and then light cured to be flat in shape (see FIG. 3B).

In step 103, by spin coating or the like as above, a photosensitive material is applied onto the flat plane to adjust the plastic components by annealing or the like and then fixed, thereby forming the photosensitive layer (see FIG. 3C).

In step 104, the photosensitive layer 11 thus fixed is exposed to an interference pattern using a two-beam interference standing wave, as shown with symbols 15A and 15B in FIG. 2, to form the reflection hologram layer 12, and further post cured to be fixed (see FIG. 3D).

In step 105, a transparent spacer material such as photocurable or thermosetting resin is deposited on the aforementioned reflection hologram layer 12, for example, by spin coating, slot coating, or screen printing, and then hardened or a polycarbonate sheet is affixed thereto, thereby forming a transparent spacer layer 16 (see FIG. 3E).

In step 106, the steps 103, 104, and 105 are repeated to deposit a predetermined number of reflection hologram layers 12 and spacer layers 16. Furthermore, in step 107, the protection layer 20 is formed on the topmost reflection hologram layer 12, thereby completing the optical recording medium 10 (see FIG. 3F).

In this exemplary embodiment, like the support substrate for the Blu-ray Disc, the support substrate 18 has the groove 19 and the reflective layer 22 at a track pitch of 0.32 μm, and thus can be manufactured or recorded/reproduced using the existing manufacturing equipment, information recording apparatus, and reproduction apparatus for the Blu-ray Disc. The support substrate 18 may also have a track pitch of 0.74 μm. In this case, it is possible to use manufacturing equipment and recording and reproduction apparatus for DVDs.

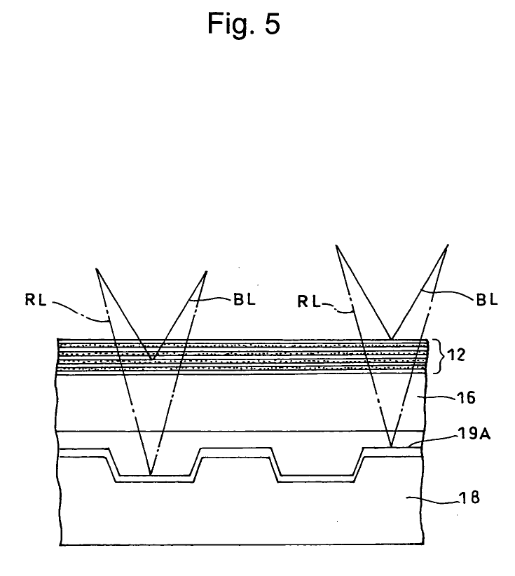

Furthermore, to use a servo laser beam of a wavelength different from one for a recording/reproduction laser beam, the track pitch may also be 0.74 μm as for DVDs. More specifically, as shown in FIG. 5, a red laser beam RL through an optical system with a numerical aperture NA=0.65 is scanned alternately across a land 19A and the groove 19 (the track is 0.32 μm). At the same time, a blue laser beam BL through an optical system with NA=0.85 is scanned across the reflection hologram layer 12 in front of the land and groove (above in FIG. 5). Note that the step height between the land 19A and the groove 19 needs to be less than the thickness of the reflection hologram layer 12.

In the first exemplary embodiment, a photosensitive layer 11 is formed on the groove 19. Thus, the groove 19 can be used as a servo layer when the reflection hologram layer 12 is formatted by two-beam interference. Furthermore, the groove 19 can also be used to read a diffracted beam from the reflection hologram layer 12 or to record a local transformation by thermal deformation (erasing the reflection hologram layer 12).

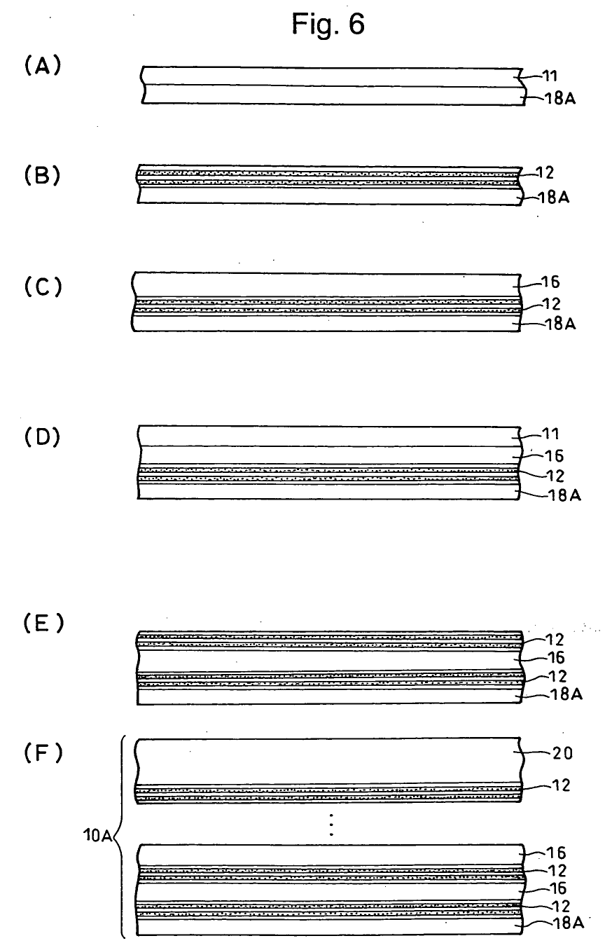

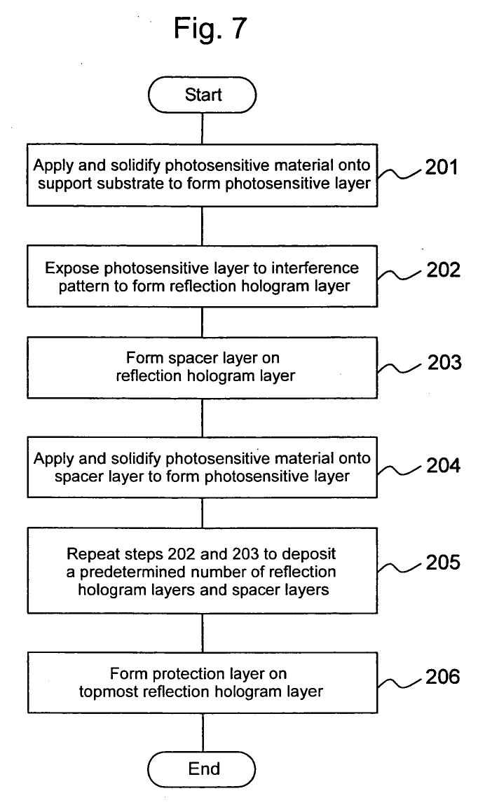

With reference to FIGS. 6 and 7, a description will now be made to a method for manufacturing an optical recording medium according to a second exemplary embodiment of the present invention.

In the second exemplary embodiment, a flat-plate shaped support substrate 18A without any concave and convex portions is used in place of the support substrate 18 having the aforementioned groove 19.

To manufacture an optical recording medium 10A according to the second exemplary embodiment, first in step 201 shown in FIG. 7, a photosensitive material is applied onto the support substrate 18A and then fixed to form the photosensitive layer 11 (see FIG. 6A).

Next, in step 202, the photosensitive layer 11 is exposed to an interference pattern to form a reflection hologram, which is then fixed to thereby form the reflection hologram layer 12 (see FIG. 6B).

In step 203, as shown in FIG. 3C, a spacer material similar to that used in step 105 above is deposited on the reflection hologram layer 12, formed as above, by spin coating or the like or affixing a polycarbonate sheet thereto, thereby forming a transparent spacer layer 16.

In step 204, as in step 201, a photosensitive material is applied onto the aforementioned spacer layer 16 and solidified to form the photosensitive layer 11 (see FIG. 6D).

In step 205, steps 202 to 203 above are repeated to form a predetermined number of reflection hologram layers 12 and a spacer layer 16 therebetween (see FIG. 6E).

In step 206, the protection layer 20 is formed on the topmost reflection hologram layer 12, thereby completing the optical recording medium 10A according to the manufacturing method of the second exemplary embodiment (see FIG. 6F).

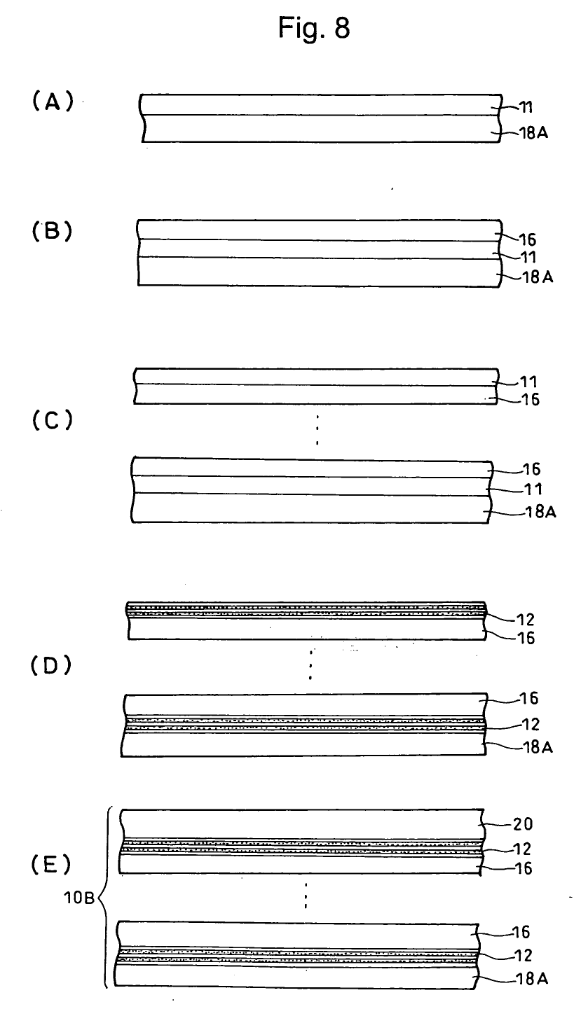

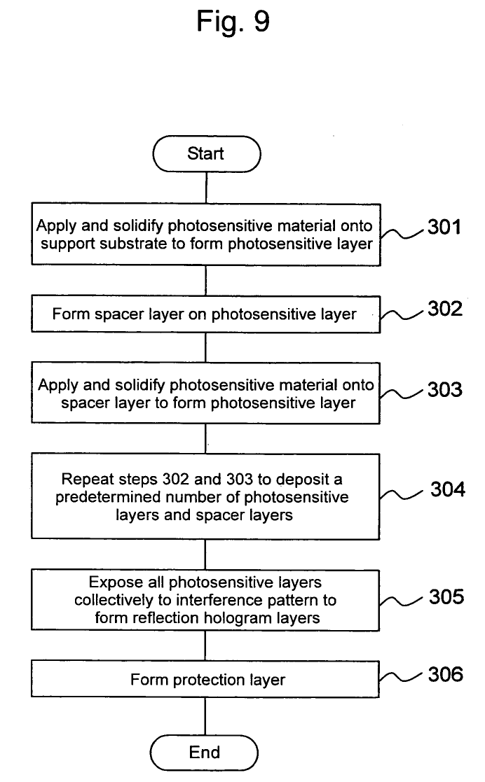

With reference to FIGS. 8 and 9, a description will now be made to a method for manufacturing an optical recording medium according to a third exemplary embodiment of the present invention.

In the third exemplary embodiment, the photosensitive layer 11 and the spacer layer 16 are alternately deposited on the support substrate 18A, and after a predetermined number of layers have been deposited, all the photosensitive layers 11 are collectively exposed to an interference pattern to realize the reflection hologram layer 12.

More specifically, as shown in FIG. 8A, in step 301, a photosensitive material is applied onto the support substrate 18A and then solidified to thereby form the photosensitive layer 11. Next, in step 302, the spacer layer 16 is formed on the photosensitive layer 11 (see FIG. 8B). In step 303, a photosensitive material is applied onto the spacer layer 16 and solidified to form the photosensitive layer 11. In step 304, steps 302 and 303 are repeated to alternately deposit a predetermined number of photosensitive layers 11 and spacer layers 16 (see FIG. 8C).

Then, in step 305, all the photosensitive layers 11 are collectively exposed to an interference pattern to form the reflection hologram layer 12 (see FIG. 8D).

Finally, in step 306, as shown in FIG. 8E, the protection layer 20 is formed on the outermost (the topmost in the figure) of the reflection hologram layer 12 to complete an optical recording medium 10B.

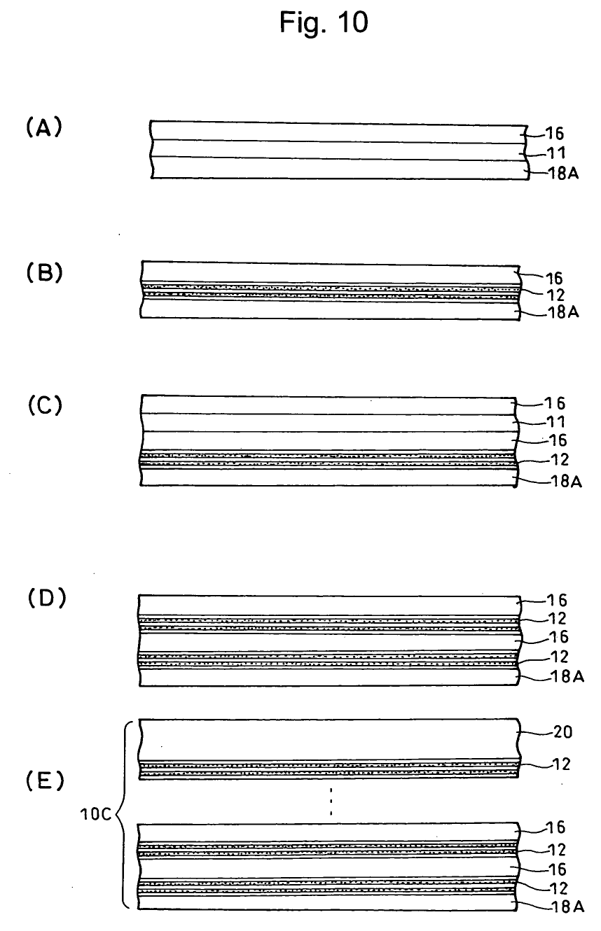

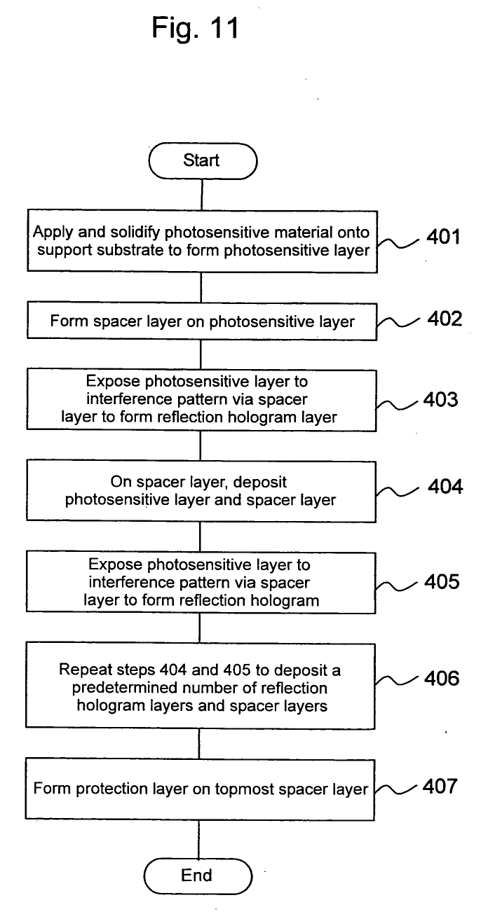

With reference to FIGS. 10 and 11, a description will now be made to a method for manufacturing an optical recording medium according to a fourth exemplary embodiment of the present invention.

In the fourth exemplary embodiment, a spacer layer is formed on a photosensitive layer, and then the photosensitive layer is exposed to an interference pattern via the spacer layer to form a reflection hologram layer.

More specifically, in step 401, as shown in FIG. 10A, a photosensitive material is applied onto the support substrate 18A and solidified to form the photosensitive layer 11. Then, in step 402, the spacer layer 16 is formed on the photosensitive layer 11 (see FIG. 10A). In step 403, as shown in FIG. 10B, the photosensitive layer 11 is exposed to an interference pattern via the spacer layer 16 to form a reflection hologram and then fixed to be the reflection hologram layer 12.

In step 404, as shown in FIG. 10C, on the spacer layer 16, a photosensitive layer 11 and a spacer layer 16 are deposited. In step 405, the photosensitive layer 11 is exposed to an interference pattern via the spacer layer 16 to form the reflection hologram layer 12 (see FIG. 10D).

In step 406, the aforementioned steps are repeated to thereby alternately deposit a predetermined number of reflection hologram layers 12 and spacer layers 16. In step 407, as shown in FIG. 10E, the protection layer 20 is formed on the outermost (the topmost in the figure) reflection hologram layer 12 to complete an optical recording medium 10C according to the fourth exemplary embodiment.

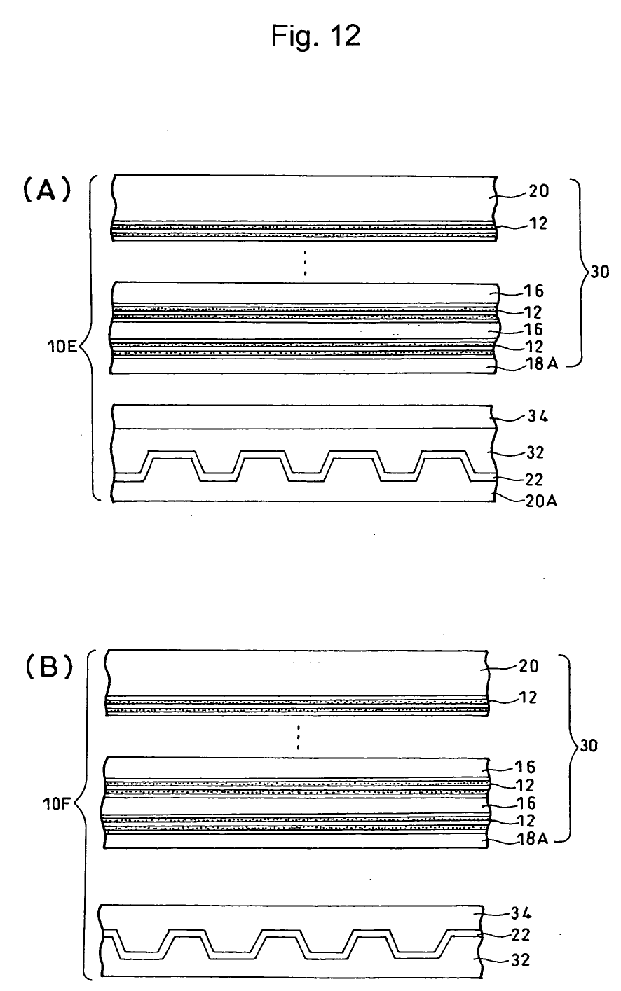

With reference to FIGS. 12A and 12B, a description will now be made to a method for manufacturing an optical recording medium according to a fifth exemplary embodiment of the present invention.

As shown in FIG. 12, the fifth exemplary embodiment is intended to manufacture the same optical recording medium 10E as the optical recording medium of FIG. 5 using a layered structure 30 of the reflection hologram layer 12 and the spacer layer 16 manufactured according to any one of the manufacturing methods of the second to fourth exemplary embodiments.

In the fifth exemplary embodiment, the reflection hologram layer 12 and the spacer layer 16 are alternately formed on one side of the support substrate 18A, and then the protection layer 20 is deposited thereon to form the layered structure 30. Subsequently, a land/groove substrate 32 with a reflective layer 22 such as metal film is adhered to the other side of the support substrate 18A via an adhesive layer 34.

Note that as shown in FIG. 12A, with the reflective layer 22 side of the land/groove substrate 32 oriented downwardly, the side opposite to the groove may be adhered to the support substrate 18A via the adhesive layer 34. Alternatively, as shown in FIG. 12(B), the reflective layer 22 of the land/groove substrate 32 may also be adhered to the support substrate 18A via the adhesive layer 34. The adhesive layer 34 may be made of, for example, a UV curable resin.

In the second to fourth exemplary embodiments and the fifth exemplary embodiment where the groove layer is adhered later, the groove can be used as a servo layer only in reproducing a formatted reflection hologram layer and recording a local transformation due to thermal deformation.

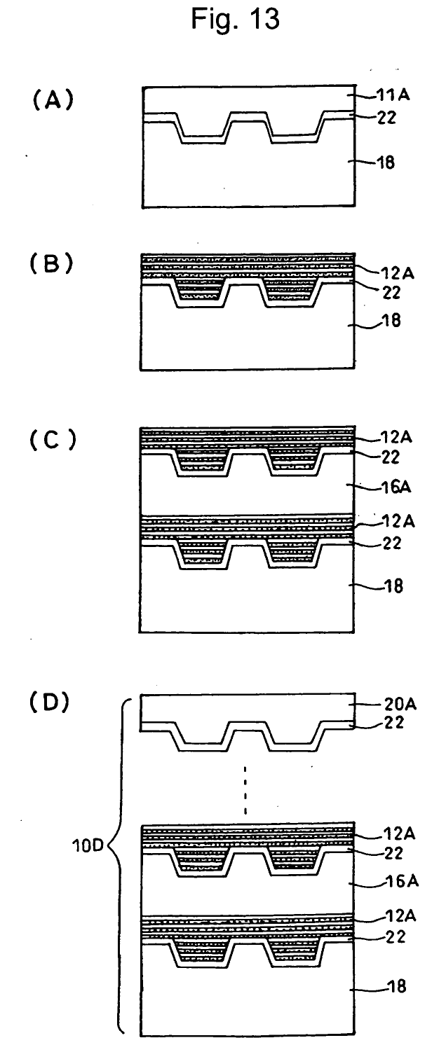

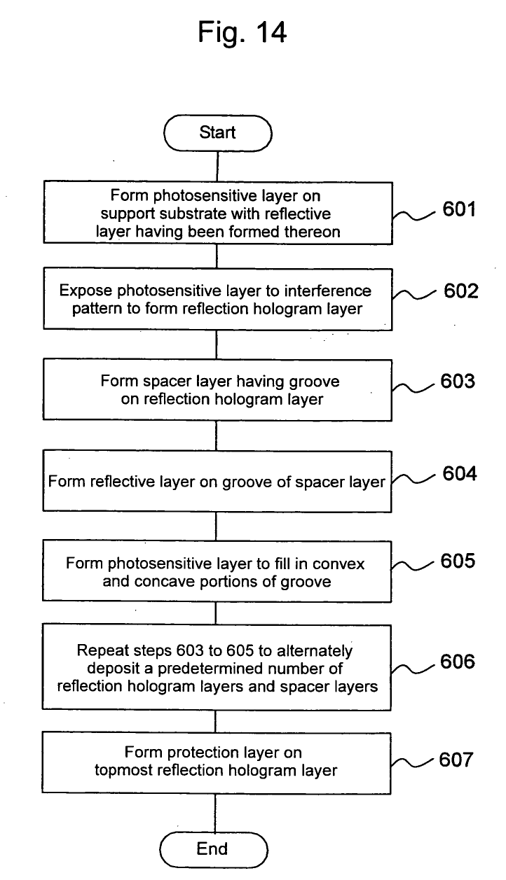

With reference to FIGS. 13 and 14, a description will now be made to a manufacturing method of an optical recording medium according to a sixth exemplary embodiment of the present invention.

The sixth exemplary embodiment is intended such that a reflection hologram layer 12A is deposited, via a spacer layer 16A, on the support substrate 18 on which the same groove 19 as that employed in the first exemplary embodiment is formed.

More specifically, as shown in FIG. 13A, in step 601 (see also FIG. 14), a photosensitive material is applied onto the support substrate 18, on which the reflective layer 22 has been formed, so that the upper surface is flat, and then solidified to form a photosensitive layer 11A.

In step 602, as shown in FIG. 13B, the photosensitive layer 11A is exposed to an interference pattern to form a reflection hologram and then fixed, thereby forming the reflection hologram layer 12A.

In step 603, a spacer material is deposited on the aforementioned reflection hologram layer 12A by spin coating or the like and then hardened with UV ray exposure, if required. At this time, as shown in FIG. 13C, the groove is transferred or stripped off through the 2P process or the like to form a spacer layer 16A which has the same groove as the concave and convex portions on the support substrate 18A.

Furthermore, in step 604, the reflective layer 22 is formed on the groove of the spacer layer 16A in the same manner as on the support substrate 18. In step 605 that follows, a photosensitive layer 11A is formed, as in step 601, so as to fill in the aforementioned concave and convex portions. Additionally, as in step 602, the photosensitive layer 11A is exposed to an interference pattern to form the reflection hologram layer 12A (see FIG. 13C).

Subsequently, in step 606, the steps are repeated in the same manner as above, thereby depositing a predetermined number of reflection hologram layers 12A and spacer layers 16A. In step 607, as shown in FIG. 13D, a protection layer 20A is formed on the outermost reflection hologram layer 12A, thus completing the optical recording medium 10D according to the sixth exemplary embodiment.

### EXAMPLES

The present inventor simulated the reflectivity of each layer and an increase in temperature of each layer in an optical recording medium with twenty (20) reflection hologram layers formed therein.

As shown in Table 1 in more detail, the refractive index is n=1.62 for both the reflection hologram layer and the spacer layer; and the extinction coefficient is k=3.0E-04 for the reflection hologram layer and 0 for the spacer layer. The change in refractive index Δni, resulting from the absorption at the reflection hologram layer, is Δn=3.0E-03 for the reflection hologram layer and 0 for the spacer layer. The thickness is 3 μm for the reflection hologram layer and 9 μm for the spacer layer. As a specific material, the aforementioned reflection hologram layer is made of a photopolymer incorporating a monomer that has absorption at the wavelength of the recording laser beam. The spacer layer was made of polycarbonate.

TABLE 1

| | Reflection hologram layer | Spacer layer |
|---|---|---|
| n | 1.62 | 1.62 |
| k | 3.0E−04 | 0 |
| Δn | 3.0E−03 | 0 |
| d(um) | 3 | 9 |

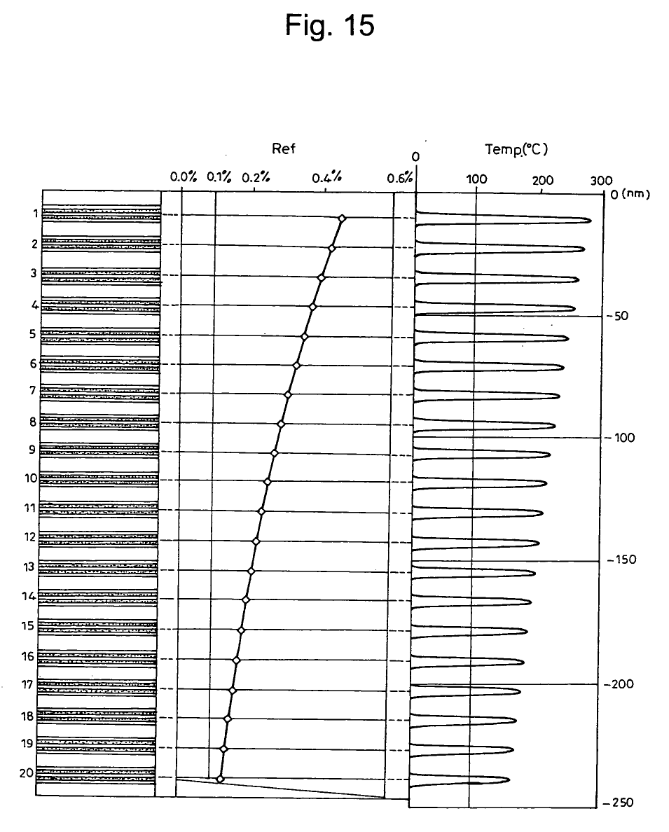

As shown in the left column of FIG. 15, an optical recording medium having twenty reflection hologram layers with a spacer layer deposited therebetween was irradiated at each reflection hologram layer with a focused laser beam from an optical system of a numerical aperture of NA=0.85. The laser beam had a wavelength of 405 nm and was emitted at a recording power of 20 mW. In this case, the reflectivity and the increase in temperature of each reflection hologram layer were as shown in the center and right columns of FIG. 15. The leftmost numbers of FIG. 15 show the sequential order of the reflection hologram layers from the side of incidence of the laser beam.

The simulation showed the following results due to the fact that the spacer layer is insensitive to a laser beam and has a low extinction coefficient. That is, the twentieth reflection hologram layer or the farthest from the side of incidence of the laser beam has a reflectivity of greater than 0.01%. The reflection hologram layer nearest to the side of incidence is about 0.45% in reflectivity. Either reflectivity thus satisfies 0.01% or greater which is required for detection upon readout. Furthermore, as for the increase in temperature at each reflection hologram layer when being irradiated with the laser beam, it was above 150° C. for the twentieth, farthest reflection hologram layer, and greater than 100° C. at all the layers.

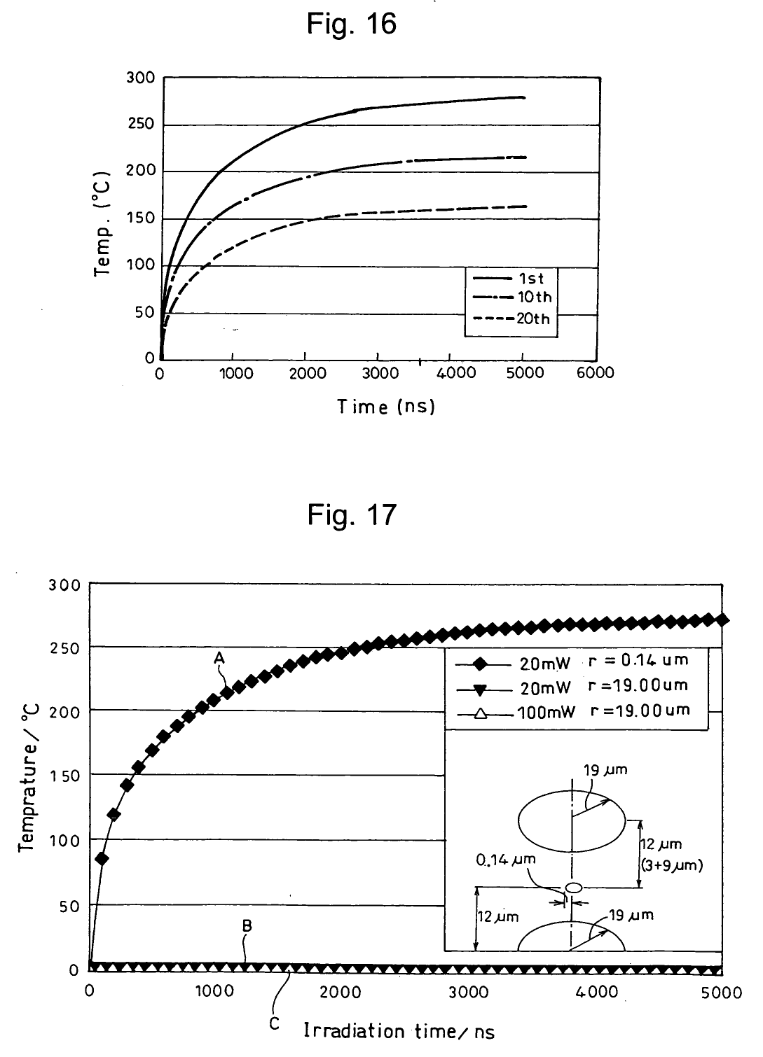

The relationship between the increase in temperature at the first, tenth, and twentieth reflection hologram layers from the side of incidence of the laser beam and the time is as shown in FIG. 16. From FIG. 16, it can be seen that the increase in temperature at the farthest reflection hologram layer from the side of light incidence is above 100° C. in about 500 nS from the start of the layer being irradiated.

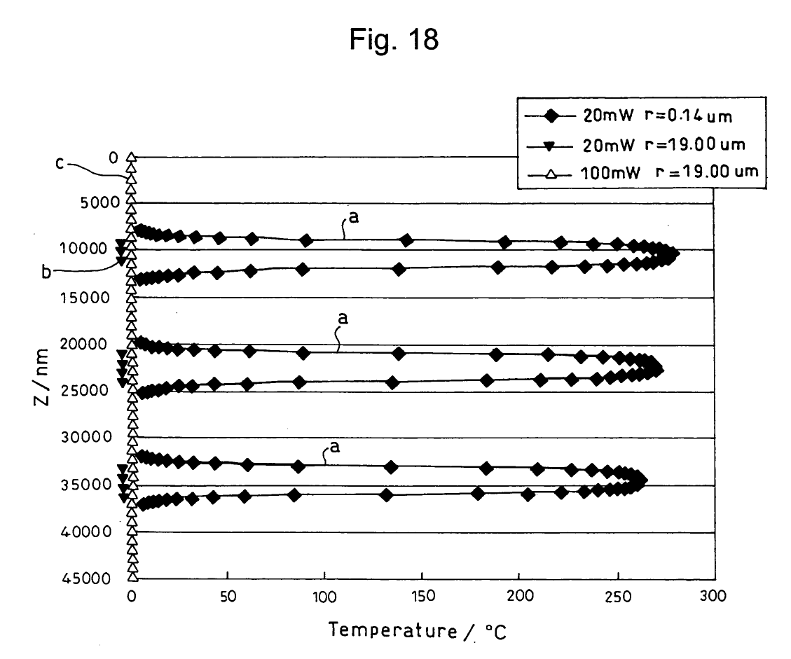

Note that as shown in FIGS. 17 and 18, in the reflection hologram layers other than those at the focal position of the laser beam, there was almost no increase in temperature and thus 100° C. was not exceeded. In FIG. 17, curve A shows the relationship between the duration of irradiation with the laser beam at a power of 20 mW and the increase in temperature of the reflection hologram layer at the focal position of the laser beam. Additionally, also shown are the relationships between the increase in temperature and the duration of irradiation with the laser beams at reflection hologram layers adjacent to the reflection hologram layer at the focal position. In this case, curve B indicated with “▾” symbols shows the relationship at a laser power of 20 mW and curve C with “Δ” symbols at 100 mW.

Note that the beam radius of the laser beam at the focal position was 0.14 μm which corresponded to 1/e of the laser intensity distribution, while the radius of the laser beam at the position of an adjacent reflection hologram layer was 19.00 μm in relation to the thickness of the spacer layer.

From FIG. 17, it can be seen that there is almost no increase in temperature of a reflection hologram layer adjacent to the reflection hologram layer at the focal position, even when being irradiated with the laser beam at a power of 100 mW.

FIG. 18 shows the results of simulations which were performed on the increase in temperature at the first to third reflection hologram layers from the side of incidence of the laser beam and the spacer layers therebetween in relation to the depth Z from the laser beam incidence side. In FIG. 18, curve “a” shows the relationship between the increase in temperature and Z at the reflection hologram layer at the focal position when being irradiated with the laser beam at a power of 20 mW. Curve “b” shows the relationship between the increase in temperature and Z at a reflection hologram layer adjacent to the reflection hologram layer at the focal position when being irradiated with the laser beam at a power of 20 mW. Curve “c” shows the relationship between the increase in temperature and Z at the adjacent reflection hologram layer when being irradiated with a laser beam of an increased power of 100 mW.

From FIG. 18, it can be seen that there was almost no increase in temperature at the adjacent reflection hologram layer and spacer layer.

As described above, since the increase in temperature of any one of the twenty reflection hologram layers is 100° C. or greater at the focal position of the laser beam, the irradiation with the laser beam makes it possible for absorbed heat to change diffraction conditions. Furthermore, almost no increase in temperature is observed at a reflection hologram layer and a spacer layer, which are adjacent to the reflection hologram layer at the focal position, and outside the laser beam at the reflection hologram layer at the focal position. It can be therefore seen that at non-focal positions of the recording laser beam, there is no increase in temperature that is enough to cause a change in hologram diffraction conditions. Furthermore, since all the twenty reflection hologram layers have a reflectivity greater than 0.01%, each layer can be reproduced one by one by being irradiated with a reproduction laser beam.

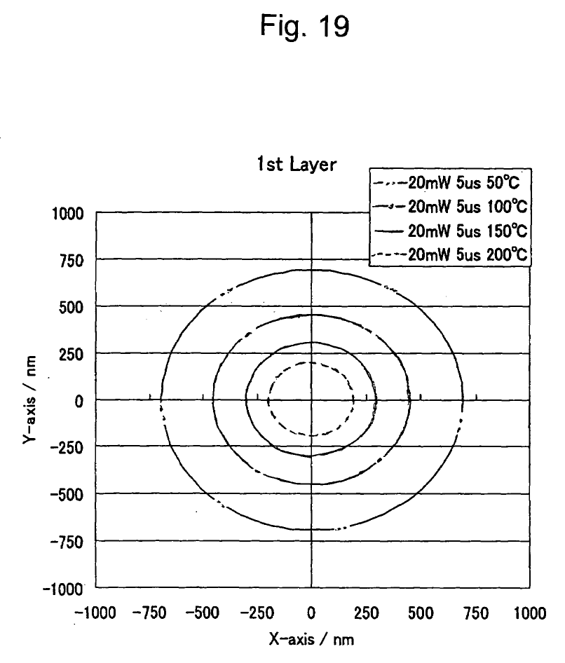

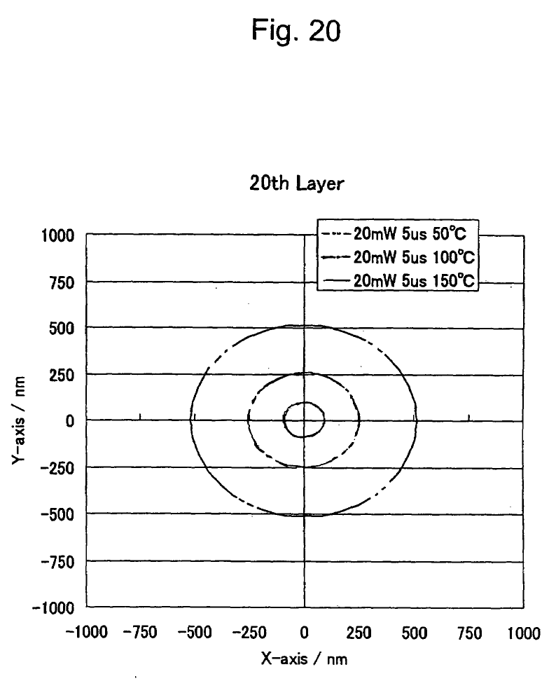

FIG. 19 shows the results of simulations which were performed on the X-Y position (perpendicular to depth Z) about the beam spot of the laser beam at the first reflection hologram layer from the side of incidence of the laser beam in relation to the increase in temperature. Furthermore, FIG. 20 shows the results of simulations which were performed on the X-Y position about the beam spot of the laser beam at the 20th reflection hologram layer from the side of incidence of the laser beam in relation to the increase in temperature.

FIGS. 19 and 20 show the curves that were plotted at temperatures of 200° C., 150° C., 100° C., and 50° C. when the laser beams were emitted at a power of 20 mW for a duration of 5 μS.

From FIGS. 19 and 20, it can be seen that in the first layer, the area at 100° C. or higher has a diameter of about 900 nm. It is also seen from FIG. 20 that the area at 100° C. or higher has a diameter of about 500 nm.

The shortest mark length 2T which is formed by a blue laser beam BL through an optical system with NA=0.85 is 149 nm. Thus, even when the shortest mark length 2T is 149 nm, arbitrary control of further increases in temperature by selecting the recording power and its duration of time makes it possible to prevent changes in diffraction conditions caused by a region outside the length being irradiated with a laser beam at a recording wavelength.

The optical recording medium according to the present invention has a spacer layer insensitive to a laser beam of a recording wavelength and a smaller extinction coefficient than that of a reflection hologram layer. Thus, an absorption contrast is formed in the reflection hologram layer and the spacer layer. Accordingly, variations in diffraction conditions due to deformation caused by locally absorbed heat can be readily provided in the reflection hologram layer, thereby allowing for recording information with accuracy.

What is claimed is:

1. An optical recording medium comprising an information recording layer formed of a plurality of reflection hologram layers, the information recording layer being irradiated with a recording laser beam to record information as a local transformation within the reflection hologram layers, wherein
the plurality of reflection hologram layers are stacked in layers with a spacer layer interposed therebetween, and
the spacer layer is insensitive to a recording wavelength laser beam and has a smaller extinction coefficient than that of the reflection hologram layers.

2. The optical recording medium according to claim 1, wherein the reflection hologram layer is made of a material having a thermal threshold value which allows, when being irradiated with a focused recording laser beam,
at a focal position, local absorbed heat to vary diffraction conditions to form a local transformation, thereby recording information, and
at a non-focal position, the diffraction conditions to be maintained.

3. The optical recording medium according to claim 1, wherein a number, a thickness, and a material of the reflection hologram layers, and a number and an extinction coefficient of the spacer layers are selected such that all diffracted beams obtained when each reflection hologram layer is irradiated with a focused reproduction laser beam have a reflectivity greater than 0.01%, and an increase in temperature at a position of a reflection hologram layer irradiated with a focused recording laser beam is greater than 100° C.

4. The optical recording medium according to claim 1, wherein:
the reflection hologram layer and the spacer layer are alternately deposited on one side of a support substrate having a servo pit or groove on the one side; and
a protection layer is formed outside an outermost reflection hologram layer.

5. The optical recording medium according to claim 4, wherein a reflective layer is formed on a surface of the servo pit or groove of the support substrate.

6. The optical recording medium according to claim 4, wherein the reflection hologram layer is formed such that the one side has a cross-sectional shape along the servo pit or groove, and its opposite side is flat in shape.

7. The optical recording medium according to claim 4, wherein the support substrate is of a disc shape, and the servo pit or groove has a track pitch of any of 0.32 μm and 0.74 μm.

8. A method for manufacturing an optical recording medium, the method comprising the steps of:
forming a photosensitive layer on one side of a support substrate;
forming a reflection hologram layer by exposing the photosensitive layer to an interference pattern and fixing a reflection hologram having been formed by the exposure to the interference pattern;
on the reflection hologram layer, forming a spacer layer being insensitive to a laser beam of a recording wavelength and having a smaller extinction coefficient than that of the reflection hologram layer; and
alternately depositing a plurality of reflection hologram layers and spacer layers on the spacer layer by repeating the steps of sequentially forming a photosensitive layer, a reflection hologram layer, and a spacer layer in the same manner as above, wherein
the reflection hologram layer is made of a material whose diffraction conditions vary, when being irradiated with a recording laser beam, as a local transformation at a focal position.

9. A method for manufacturing an optical recording medium, the method comprising the steps of:
forming a photosensitive layer on one side of a support substrate;
forming a spacer layer on the photosensitive layer, the spacer layer being insensitive to a laser beam of a recording wavelength;
forming a reflection hologram layer by exposing the photosensitive layer to an interference pattern via the spacer layer and fixing a reflection hologram having been formed by the exposure to the interference pattern; and
alternately depositing a plurality of reflection hologram layers and spacer layers on the spacer layer by repeating the steps of sequentially forming a photosensitive layer and a spacer layer and forming a reflection hologram layer by the exposure to an interference pattern in the same manner as above, wherein
the reflection hologram layer is made of a material whose diffraction conditions vary, when being irradiated with a recording laser beam, as a local transformation at a focal position, and the spacer layer is formed to have a smaller extinction coefficient than that of the reflection hologram layer.

10. A method for manufacturing an optical recording medium, the method comprising the steps of:
forming a photosensitive layer on one side of a support substrate;
forming a spacer layer on the photosensitive layer, the spacer layer being insensitive to a laser beam of a recording wavelength;
alternately depositing a plurality of photosensitive layers and spacer layers on the spacer layer by repeating steps of sequentially forming a photosensitive layer and a spacer layer in the same manner as above; and
forming a reflection hologram layer by collectively exposing the plurality of stacked photosensitive layers to an interference pattern and fixing a reflection hologram having been formed by the exposure to the interference pattern, wherein
the reflection hologram layer is made of a material whose diffraction conditions vary, when being irradiated with a recording laser beam, as a local transformation at a focal position, and the spacer layer is formed to have a smaller extinction coefficient than that of the reflection hologram layer.

11. The method for manufacturing an optical recording medium according to claim 8, wherein the support substrate has a servo pit or groove, and the method comprising the steps of:
pre-forming a reflective layer of a dielectric material on the servo pit or groove of the support substrate;
on the photosensitive layer that is formed on the reflective layer, depositing repeatedly a spacer layer, a reflective layer, and a photosensitive layer in that order; and
before forming the reflective layer on each of the spacer layers, forming on the spacer layer a servo groove similar to the servo groove.

12. A method for manufacturing an optical recording medium, comprising the step of:
affixing one side of a land/groove substrate having a reflective layer formed on a land/groove side via an adhesive layer to one side of a support substrate of a layered structure, the layered structure having a plurality of reflection hologram layers and spacer layers alternately deposited on the other side of the support substrate, wherein
the reflection hologram layer is made of a material whose diffraction conditions vary, when being irradiated with a recording laser beam, as a local transformation at a focal position, and the spacer layer is formed to have a smaller extinction coefficient than that of the reflection hologram layer.
